(19) United States
(12) Patent Application Publication
(10) Pub. No.: US 2026/0182393 A1
(43) Pub. Date: Jun. 25, 2026

(54) METHOD OF FABRICATING SEMICONDUCTOR PACKAGE

(71) Applicant: SK hynix Inc., Gyeonggi-do (KR)

(72) Inventor: Heon Yong CHANG, Gyeonggi-do (KR)

(21) Appl. No.: 19/203,187

(22) Filed: May 9, 2025

(30) Foreign Application Priority Data
Dec. 23, 2024 (KR) 10-2024-0193725

(51) Int. Cl. H01L 23/00; H01L 21/48; H01L 21/56; H01L 23/31; H01L 23/498; H01L 25/065; H01L 25/18; H10B 80/00; H10D 80/30

(52) U.S. Cl. CPC H10W 70/093; H10W 74/016; H10W 74/121; H10W 90/00; H10W 90/701; H10B 80/00; H10D 80/30; H10W 72/01551; H10W 72/07511; H10W 72/877; H10W 72/884; H10W 90/24; H10W 90/724; H10W 90/732; H10W 90/734; H10W 90/754

(57) ABSTRACT

A method of fabricating a semiconductor package according to embodiments of the present disclosure may include: disposing a semiconductor chip on a first molding layer; forming a vertical wire on a chip pad of the semiconductor chip; forming, with the vertical wire fixed with a holder, a second molding layer on the first molding layer such that the second molding layer seals the semiconductor chip and the vertical wire; removing the holder; and forming a redistribution layer on the second molding layer and the vertical wire.

### CROSS-REFERENCE TO RELATED APPLICATION

The present application claims priority under 35 U.S.C. § 119(a) to Korean Patent Application No. 10-2024-0193725 filed in the Korean Intellectual Property Office on Dec. 23, 2024, which is incorporated herein by reference in its entirety.

### BACKGROUND

### 1. Technical Field

Embodiments of the present disclosure relate to a method of fabricating a semiconductor package.

### 2. Related Art

A semiconductor chip includes an integrated circuit for storing or processing data. In addition, the semiconductor chip includes chip pads for inputting data to the integrated circuit or outputting data of the integrated circuit to the outside. A semiconductor package serves to electrically connect the semiconductor chip to an external device.

Various methods may be applied to electrically connect chip pads to an external device. A semiconductor package using a redistribution layer has redistribution patterns that are electrically connected to the chip pads. Among semiconductor packages using a redistribution layer, a fan-out package employs a technology of extending redistribution patterns connected to chip pads to the outside of a region where a semiconductor chip is disposed, to thereby dispose external connection terminals in a region outside the semiconductor chip. The fan-out package provides advantages in that not only the number and pitch of the external connection terminals are not limited by a chip size but also a standardized ball layout may be used regardless of a chip size.

A vertical fan-out package implements a fan-out structure using vertical wires, and provides advantages in that thinning is possible because a semiconductor chip and redistribution patterns are connected by vertical wires.

### SUMMARY

Embodiments of the present disclosure are directed to providing a method of fabricating a semiconductor package.

The embodiments of the present disclosure are not limited to the implementations mentioned in this specification, and other implementations not mentioned will be clearly understood by those skilled in the art from the description below.

In an embodiment, a method of fabricating a semiconductor package may include: disposing a semiconductor chip on a first molding layer; forming a vertical wire on a chip pad of the semiconductor chip; forming, with the vertical wire fixed with a holder, a second molding layer on the first molding layer such that the second molding layer such seals the semiconductor chip and the vertical wire; removing the holder; and forming a redistribution layer on the second molding layer and the vertical wire.

In an embodiment, a method of fabricating a semiconductor package may include: disposing a first semiconductor chip on a first molding layer, the first semiconductor chip having a first chip pad; offset-stacking a second semiconductor chip on the first semiconductor chip so that the first chip pad is exposed, the second semiconductor chip having a second chip pad; forming a first vertical wire on the first chip pad, and forming a second vertical wire on the second chip pad; forming, with the first and second vertical wires fixed with a holder, a second molding layer on the first molding layer such that the second molding layer seals the first and second semiconductor chips and the first and second vertical wires; removing the holder; and forming a redistribution layer on the second molding layer and the first and second vertical wires.

In an embodiment, a method of fabricating a semiconductor package may include: offset stacking a plurality of semiconductor chips, each of the plurality of semiconductor chips having a chip pad, so that each chip pad is exposed; forming vertical wires on each of the chip pads; forming, with the vertical wires of the plurality of semiconductor chips fixed with a holder, a molding layer that seals the plurality of semiconductor chips and the vertical wires; removing the holder; and forming a redistribution layer on the second molding layer and the vertical wires, wherein the redistribution layer includes redistribution patterns with an alignment margin based on a fixed position of each of the vertical wires.

According to embodiments of the present disclosure, a method of fabricating a semiconductor package may be provided, capable of improving the alignment margin between a vertical wire and a redistribution pattern.

Effects of the embodiments of the present disclosure are not limited to those mentioned above, and other effects not mentioned will be clearly understood by those skilled in the art from the description of claims.

### BRIEF DESCRIPTION OF THE DRAWINGS

The present disclosure will be more fully understood from the detailed description to be made below and the accompanying drawings, which are provided for illustration only and are not intended to limit the present disclosure.

FIG. 1 to FIG. 6 are cross-sectional views illustrating a semiconductor package according to an embodiment of the present disclosure according to a process sequence.

FIG. 7 to FIG. 12 are cross-sectional views illustrating a semiconductor package according to an embodiment of the present disclosure according to a process sequence.

FIG. 13 is a diagram illustrating a sweeping phenomenon of a vertical wire.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked”, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the disclosure are described in detail with reference to the accompanying drawings.

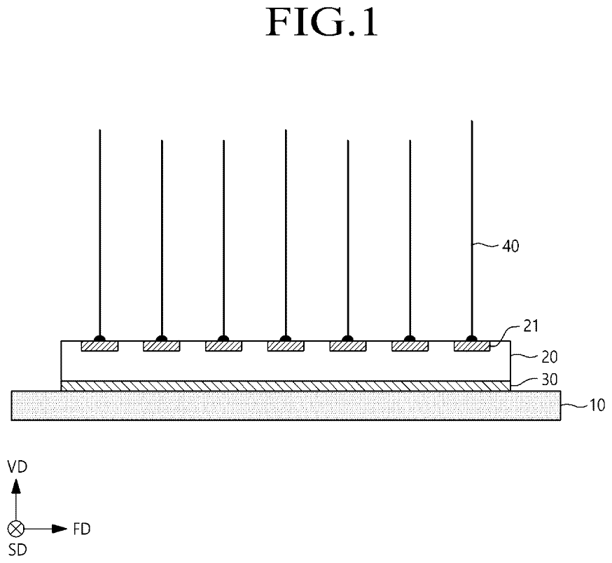

FIG. 1 to FIG. 6 are cross-sectional views illustrating a semiconductor package according to an embodiment of the present disclosure according to a process sequence.

Referring to FIG. 1, a semiconductor chip 20 is disposed on a first molding layer 10.

The first molding layer 10 includes an insulating layer. The insulating layer may include an epoxy molding compound (EMC). The epoxy molding compound may include resin and filler. The first molding layer 10 may include an epoxy molding compound film (EMC film) that is obtained by processing an epoxy molding compound (EMC) into a film form.

The semiconductor chip 20 may include nonvolatile memory such as NAND flash memory, NOR flash memory, PRAM (phase change random access memory), and MRAM (magneto-resistive random access memory), volatile memory such as DRAM (dynamic random access memory) and SRAM (static random access memory) or a processor such as a logic circuit, but is not limited thereto.

The semiconductor chip 20 has a top surface on which chip pads 21 are disposed and a bottom surface opposite to the top surface. For example, the chip pads 21 may be disposed in a first direction FD. The chip pads 21 are electrically connected to an integrated circuit inside the semiconductor chip 20.

An adhesive layer 30 is disposed on the bottom surface of the semiconductor chip 20, and the semiconductor chip 20 is attached onto the first molding layer 10 using the adhesive layer 30.

Vertical wires 40 are formed on the chip pads 21 of the semiconductor chip 20, respectively.

Each vertical wire 40 extends substantially in a vertical direction VD with its lower end connected to a corresponding chip pad 21. The vertical wire 40 extends in the vertical direction VD from the surface of the corresponding chip pad 21 or is erected in the vertical direction VD. The vertical wire 40 may include gold (Au).

Among the vertical wires 40, there may be vertical wires 40 whose lengths in the vertical direction VD are different from each other. The upper ends of the vertical wires 40 that have different lengths may be disposed at different height levels in the vertical direction VD from the top surface of the semiconductor chip 20.

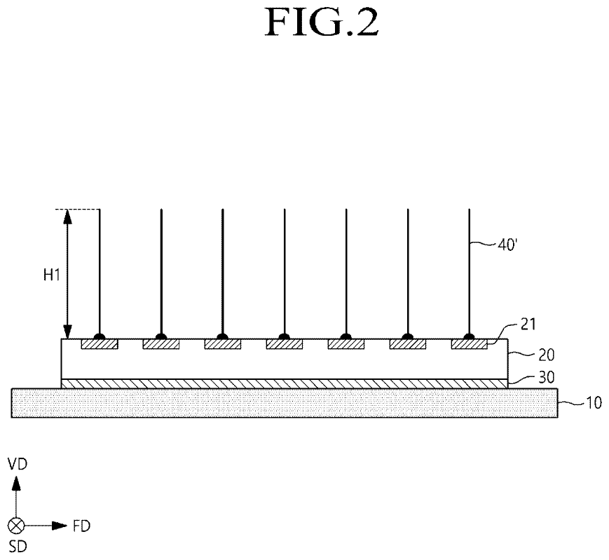

Referring to FIG. 2, the vertical wires 40 of FIG. 1 are trimmed to form vertical wires 40′.

In the trimming process, the vertical wires 40 are cut so that the upper ends of the vertical wires 40′ are disposed at the same height level in the vertical direction VD from the top surface of the semiconductor chip 20. As in the example illustrated in FIG. 2, the upper ends of the trimmed vertical wires 40′ are disposed at a height level of H1 in the vertical direction VD from the top surface of the semiconductor chip 20. The trimming process is optional and may be omitted.

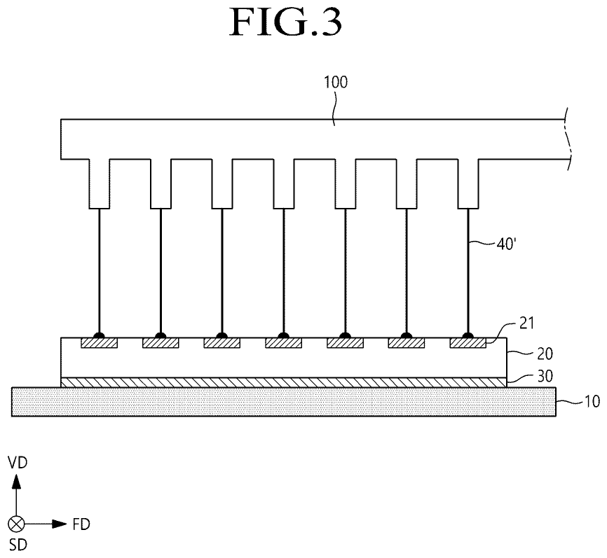

Referring to FIG. 3, the vertical wires 40′ are fixed by a holder 100.

The vertical wires 40′ are fixed by clamping the upper ends of the vertical wires 40′ with the holder 100 to apply tension to the vertical wires 40′.

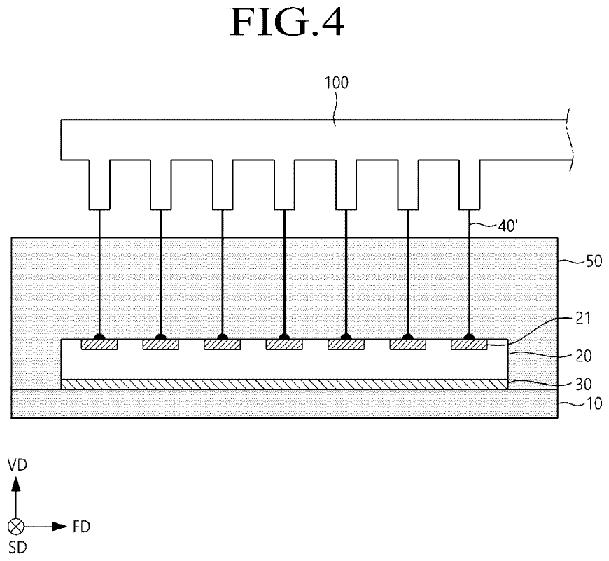

Referring to FIG. 4, with the vertical wires 40′ fixed with the holder 100, a pre-molding layer 50 that seals the semiconductor chip 20 and the vertical wires 40′ is formed on the first molding layer 10. The upper sections of the vertical wires 40′ are not sealed with the pre-molding layer 50 and protrude out of the top surface of the pre-molding layer 50.

The pre-molding layer 50 may be formed by dispensing a liquid molding member onto the first molding layer 10 and the semiconductor chip 20. The pre-molding layer 50 may be formed by, for example, forming a dam that sets an area in which the liquid molding member is to be contained, dispensing the liquid molding member into the area surrounded by the dam to an extent that the semiconductor chip 20 and the lower sections of the vertical wires 40′ are covered and then curing the liquid molding member.

The holder 100 may apply tension to the vertical wires 40′ to prevent the vertical wires 40′ from being swept in a direction in which pressure by the flow of the liquid molding member is applied.

The pre-molding layer 50 includes an insulating layer. The insulating layer may include an epoxy molding compound (EMC). The epoxy molding compound may include resin and filler.

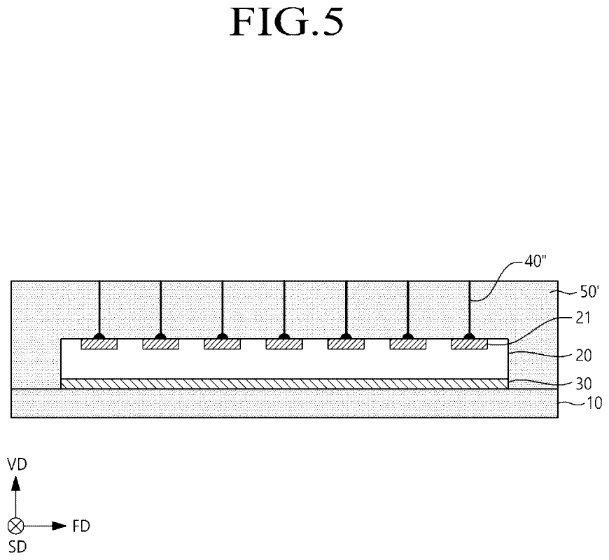

The pre-molding layer 50 is a pre-structure for forming a second molding layer 50′ of FIG. 5, and may have a thickness thicker than the second molding layer 50′.

Referring to FIG. 5, by removing the holder 100 of FIG. 4 and performing a polishing process on the pre-molding layer 50 of FIG. 4, the second molding layer 50′ is formed.

During the polishing process, the vertical wires 40′ of FIG. 4 are polished together with the pre-molding layer 50 of FIG. 4. Accordingly, the upper ends of vertical wires 40″ after the polishing process may be disposed at substantially the same height level as the top surface of the second molding layer 50′ in the vertical direction VD.

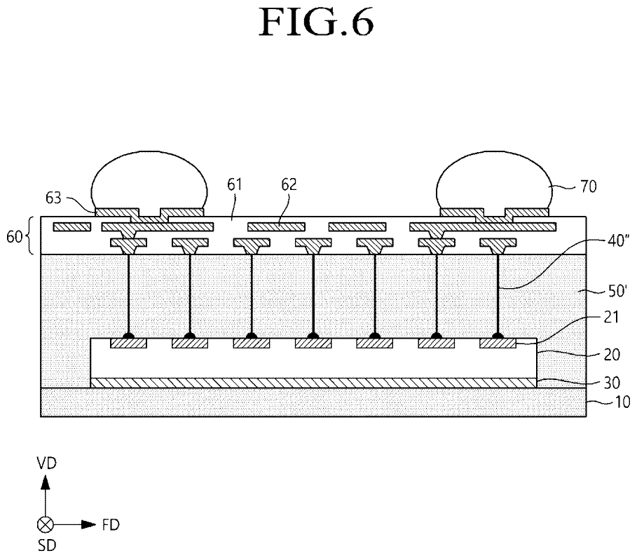

Referring to FIG. 6, a redistribution layer 60 is formed on the second molding layer 50′ and the vertical wires 40″.

The redistribution layer 60 includes an insulating layer 61 and redistribution patterns 62.

The redistribution patterns 62 are connected to the vertical wires 40″, and are connected to the chip pads 21 of the semiconductor chip 20 through the vertical wires 40″. The redistribution patterns 62 are isolated from each other by the insulating layer 61.

Some of the redistribution patterns 62 include under bump metallurgies (UBMs) 63. An external connection terminal 70 is connected to each UBM 63. The UBM 63 serves as a wetting layer so that the external connection terminal 70 may be well adhered. The external connection terminal 70 may be connected to one of the vertical wires 40″ through redistribution patterns 62. The external connection terminal 70 includes a solder ball.

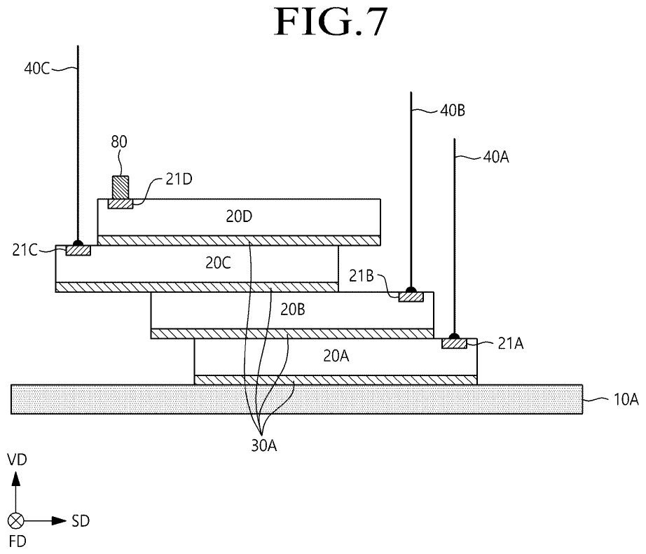

FIG. 7 to FIG. 12 are cross-sectional views illustrating a semiconductor package according to an embodiment of the present disclosure according to a process sequence.

Referring to FIG. 7, first, second, third and fourth semiconductor chips 20A, 20B, 20C, and 20D are sequentially stacked on a first molding layer 10A.

In the embodiment described herein with reference to the accompanying drawings, the number of semiconductor chips to be stacked is four, but is not limited thereto. The number of semiconductor chips to be stacked may be two or more.

Each of the first, second, third and fourth semiconductor chips 20A, 20B, 20C, and 20D may include nonvolatile memory such as NAND flash memory, NOR flash memory, PRAM, and MRAM, volatile memory such as DRAM and SRAM or a processor such as a logic circuit, but is not limited thereto.

The first semiconductor chip 20A has a top surface on which a first chip pad 21A is disposed and a bottom surface opposite to the top surface. The first chip pad 21A is electrically connected to a first integrated circuit inside the first semiconductor chip 20A. The first chip pad 21A is disposed on one of both side edges of the top surface of the first semiconductor chip 20A in a second direction SD, for example, a right-side edge.

The second semiconductor chip 20B is disposed on the first semiconductor chip 20A. The second semiconductor chip 20B is offset with respect to the first semiconductor chip 20A so that the first chip pad 21A is exposed.

The second semiconductor chip 20B has a top surface on which a second chip pad 21B is disposed and a bottom surface opposite to the top surface. The second chip pad 21B is electrically connected to a second integrated circuit inside the second semiconductor chip 20B. The second chip pad 21B is disposed on one of both side edges of the top surface of the second semiconductor chip 20B in the second direction SD, for example, a right-side edge.

The third semiconductor chip 20C is disposed on the second semiconductor chip 20B. The third semiconductor chip 20C is offset with respect to the second semiconductor chip 20B so that the second chip pad 21B is exposed.

The third semiconductor chip 20C has a top surface on which a third chip pad 21C is disposed and a bottom surface opposite to the top surface. The third chip pad 21C is electrically connected to a third integrated circuit inside the third semiconductor chip 20C. The third chip pad 21C is disposed on one of both side edges of the top surface of the third semiconductor chip 20C in the second direction SD, for example, a left-side edge.

The fourth semiconductor chip 20D is disposed on the third semiconductor chip 20C. The fourth semiconductor chip 20D is offset with respect to the third semiconductor chip 20C so that the third chip pad 21C is exposed.

The fourth semiconductor chip 20D has a top surface on which a fourth chip pad 21D is disposed and a bottom surface opposite to the top surface. The fourth chip pad 21D is electrically connected to a fourth integrated circuit inside the fourth semiconductor chip 20D. The fourth chip pad 21D is disposed on one of both side edges of the top surface of the fourth semiconductor chip 20D in the second direction SD, for example, a left-side edge.

A bump 80 is disposed on the fourth chip pad 21D. The bump 80 may include a metallic material. The metallic material may include gold (Au), copper (Cu), silver (Ag) or platinum (PT). Although, in the present embodiment, the bump 80 is disposed on the fourth chip pad 21D, a vertical wire may be disposed instead of the bump 80.

Adhesive layers 30A are disposed on the bottom surfaces of the first, second, third and fourth semiconductor chips 20A, 20B, 20C and 20D, and each of the first, second, third and fourth semiconductor chips 20A, 20B, 20C and 20D is attached to one of the underlying first molding layer 10A and first, second and third semiconductor chips 20A, 20B and 20C using the adhesive layer 30A.

First, second and third vertical wires 40A, 40B and 40C are connected to the first, second and third chip pads 21A, 21B and 21C, respectively. The first vertical wire 40A extends in the vertical direction VD with its lower end connected to the first chip pad 21A. The upper end of the first vertical wire 40A is disposed above the top surface of the fourth semiconductor chip 20D.

The second vertical wire 40B extends in the vertical direction VD with its lower end connected to the second chip pad 21B. The upper end of the second vertical wire 40B is disposed above the top surface of the fourth semiconductor chip 20D.

The third vertical wire 40C extends in the vertical direction VD with its lower end connected to the third chip pad 21C. The upper end of the third vertical wire 40C is disposed above the top surface of the fourth semiconductor chip 20D. The first, second and third vertical wires 40A, 40B and 40C may be formed of a conductive material. The conductive material may include gold (Au).

In an embodiment, the upper end of the first vertical wire 40A, the upper end of the second vertical wire 40B and the upper end of the third vertical wire 40C may be disposed at different height levels.

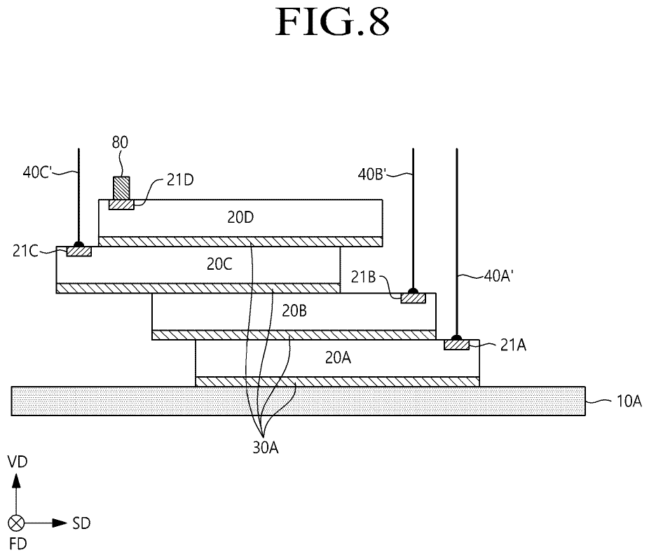

Referring to FIG. 8, the first, second and third vertical wires 40A, 40B and 40C of FIG. 7 are trimmed to form first, second and third vertical wires 40A′, 40B′ and 40C′, respectively.

In the trimming process, the first, second and third vertical wires 40A, 40B and 40C are cut so that the upper ends of the first, second and third vertical wires 40A′, 40B′ and 40C′ are disposed on substantially the same plane. The trimming process is optional and may be omitted.

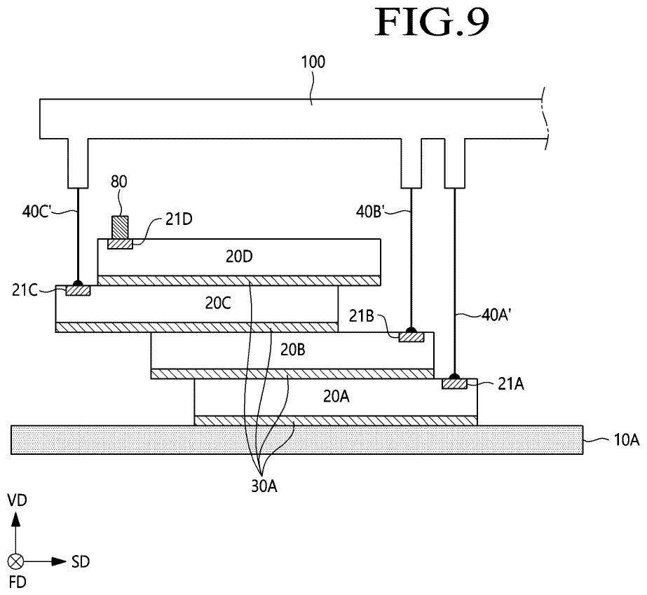

Referring to FIG. 9, the first, second and third vertical wires 40A′, 40B′ and 40C′ are fixed by a holder 100.

The first, second and third vertical wires 40A′, 40B′ and 40C′ are fixed by clamping the upper ends of the first, second and third vertical wires 40A′, 40B′ and 40C′ with the holder 100 to apply tension to the first, second and third vertical wires 40A′, 40B′ and 40C′.

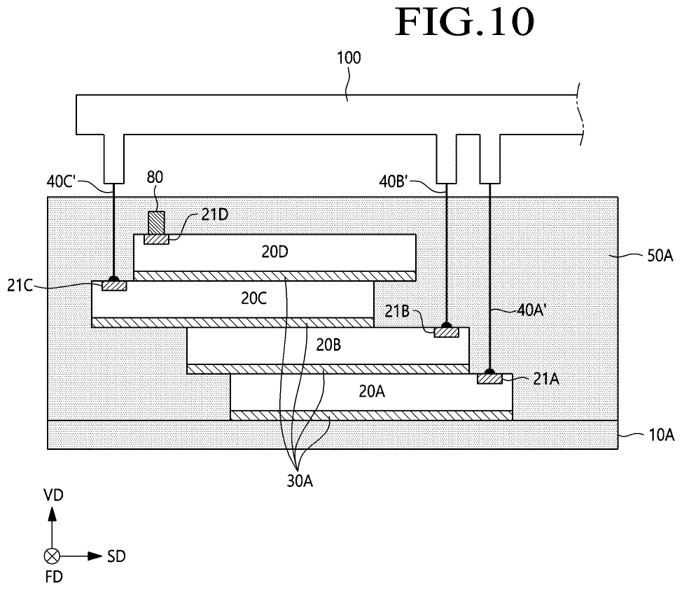

Referring to FIG. 10, with the first, second and third vertical wires 40A′, 40B′ and 40C′ fixed with the holder 100, a pre-molding layer 50A that seals the first, second, third and fourth semiconductor chips 20A, 20B, 20C and 20D, the bump 80 and the lower sections of the first, second and third vertical wires 40A′, 40B′ and 40C′ is formed on the first molding layer 10A. The upper sections of the first, second and third vertical wires 40A′, 40B′ and 40C′ protrude out of the top surface of the pre-molding layer 50A.

The pre-molding layer 50A may be formed by dispensing a liquid molding member onto the first molding layer 10A and the first, second, third and fourth semiconductor chips 20A, 20B, 20C and 20D. The pre-molding layer 50A may be formed by, for example, forming a dam that sets an area in which the liquid molding member is to be contained, dispensing the liquid molding member into the area surrounded by the dam to an extent that the first, second, third and fourth semiconductor chips 20A, 20B, 20C and 20D, the bump 80 and the lower sections of the first, second, and third vertical wires 40A′, 40B′ and 40C′ are covered and then curing the liquid molding member.

The holder 100 may apply tension to the first, second and third vertical wires 40A′, 40B′ and 40C′ to suppress the first, second and third vertical wires 40A′, 40B′ and 40C′ from being swept in a direction in which pressure by the flow of the liquid molding member is applied.

The pre-molding layer 50A includes an insulating layer. The insulating layer may include an epoxy molding compound (EMC). The epoxy molding compound may include resin and filler.

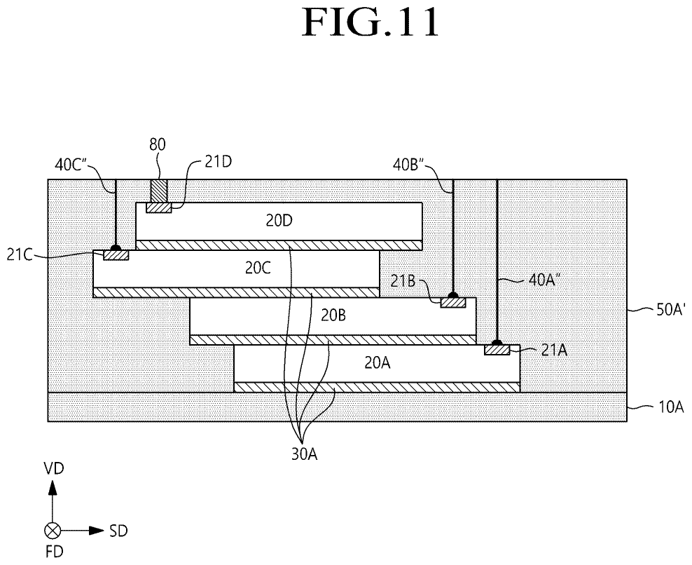

Referring to FIG. 11, the holder 100 of FIG. 10 is removed, and a second molding layer 50A′ is formed by polishing the pre-molding layer 50A. During the polishing process, the first, second and third vertical wires 40A′, 40B′ and 40C′ of FIG. 10 are polished together with the pre-molding layer 50A of FIG. 10, and the bump 80 is exposed. Accordingly, the upper ends of first, second and third vertical wires 40A″, 40B″ and 40C″ may be located at substantially the same height level as the top surface of the second molding layer 50A′ in the vertical direction VD.

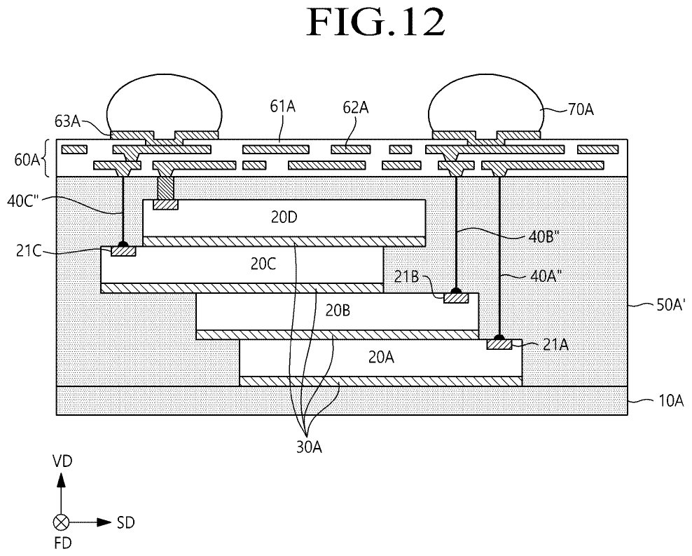

Referring to FIG. 12, a redistribution layer 60A is formed on the second molding layer 50A′, the bump 80 and the first, second and third vertical wires 40A″, 40B″ and 40C″.

The redistribution layer 60A includes an insulating layer 61A and redistribution patterns 62A.

The redistribution patterns 62A are connected to the bump 80 and the first, second, and third vertical wires 40A″, 40B″, and 40C″, and are connected to the first, second, third, and fourth chip pads 21A, 21B, 21C, and 21D through the bump 80 and the first, second, and third vertical wires 40A″, 40B″, and 40C″. The redistribution patterns 62A are isolated from each other by the insulating layer 61A.

Some of the redistribution patterns 62A include UBMs 63A. An external connection terminal 70A is connected to each UBM 63A. The external connection terminal 70A may be connected to one of the bump 80 and the first, second, and third vertical wires 40A″, 40B″, and 40C″ through redistribution patterns 62A.

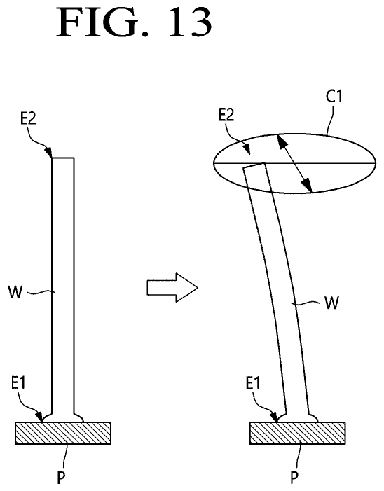

FIG. 13 is a diagram illustrating a sweeping phenomenon of a vertical wire.

Referring to FIG. 13, when pressure by the flow of a molding member is applied during a molding process, a lower end E1 of a vertical wire W is fixed by being attached to a chip pad P and thus does not move, but an upper end E2 of the vertical wire W is not fixed and thus may be swept in a direction in which pressure by the flow of the molding member is applied. That is to say, the displacement of the upper end E2 of the vertical wire W may change due to the injection direction and pressure of molding member and the eddy current of the molding member attributable to a surrounding structure. As a result of sweeping, the displacement of the upper end E2 of the vertical wire W may occur to any location within a concentric circle (C1) illustrated in the drawing.

Such a sweeping phenomenon may be exacerbated as the length of the vertical wire W increases. Because the location of the upper end E2 of the vertical wire W changes due to the sweeping, the upper end E2 of the vertical wire W and a redistribution pattern to be connected thereto may be misaligned, which may result in poor connection between the vertical wire W and the redistribution pattern.

Increasing the width of the redistribution pattern improves the alignment margin between the upper end E2 of the vertical wire W and the redistribution pattern, and therefore, it is possible to reduce poor connection between the vertical wire W and the redistribution pattern. However, as the width of the redistribution pattern increases, the spacing between neighboring redistribution patterns narrows, which increases the parasitic capacitance between the neighboring redistribution patterns, and thus, the performance of a package may deteriorate.

According to embodiments of the present disclosure, because a molding process is performed with a vertical wire fixed with a holder, it is possible to suppress or prevent the vertical wire from being swept and improve the alignment margin (for example, reduce the margin of the width required for the redistribution pattern to be aligned with the vertical wire with a good connection) between the vertical wire and a redistribution pattern. The improved alignment margins thereby allow redistribution patterns with narrower widths that may be spaced at larger distances from each other and reduce the incidence of parasitic capacitance. The redistribution layer may include redistribution patterns with an alignment margin based on (or corresponding to) a fixed position of each of the vertical wires.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A method of fabricating a semiconductor package, the method comprising:
disposing a semiconductor chip on a first molding layer;
forming a vertical wire on a chip pad of the semiconductor chip;
forming, with the vertical wire fixed with a holder, a second molding layer on the first molding layer such that the second molding layer seals the semiconductor chip and the vertical wire;
removing the holder; and
forming a redistribution layer on the second molding layer and the vertical wire.

2. The method according to claim 1, further comprising
trimming, before fixing the vertical wire with the holder, the vertical wire.

3. The method according to claim 1, wherein the vertical wire is fixed by clamping an upper end of the vertical wire with the holder.

4. The method according to claim 1, wherein the forming the second molding layer comprises:
forming a pre-molding layer that covers the semiconductor chip and the vertical wire; and
polishing the vertical wire and the pre-molding layer to form the second molding layer.

5. The method according to claim 4, wherein the pre-molding layer is formed by dispensing molding resin.

6. The method according to claim 1, wherein the redistribution layer includes an insulating layer that is disposed on the second molding layer and the vertical wire, and a redistribution pattern that is disposed in the insulating layer and is connected to the vertical wire.

7. The method according to claim 1, further comprising
forming, after forming the redistribution layer, an external connection terminal on the redistribution layer.

8. A method of fabricating a semiconductor package, the method comprising:
disposing a first semiconductor chip on a first molding layer, the first semiconductor chip having a first chip pad;
offset-stacking a second semiconductor chip on the first semiconductor chip so that the first chip pad is exposed, the second semiconductor chip having a second chip pad;
forming a first vertical wire on the first chip pad, and forming a second vertical wire on the second chip pad;
forming, with the first and second vertical wires fixed with a holder, a second molding layer on the first molding layer such that the second molding layer seals the first and second semiconductor chips and the first and second vertical wires;
removing the holder; and
forming a redistribution layer on the second molding layer and the first and second vertical wires.

9. The method according to claim 8, further comprising
trimming, before fixing the first and second vertical wires with the holder, the first and second vertical wires.

10. The method according to claim 9, wherein the trimming the first and second vertical wires includes cutting the first and second vertical wires so that an upper end of the first vertical wire and an upper end of the second vertical wire are located at the same height level.

11. The method according to claim 8, wherein the first and second vertical wires are fixed by clamping an upper end of the first vertical wire and an upper end of the second vertical wire with the holder.

12. The method according to claim 8, wherein the forming the second molding layer comprises:
forming a pre-molding layer that covers the first and second semiconductor chips and the first and second vertical wires; and
polishing the first and second vertical wires and the pre-molding layer to form the second molding layer.

13. The method according to claim 12, wherein the pre-molding layer is formed by dispensing molding resin.

14. The method according to claim 8, wherein the redistribution layer includes an insulating layer that is disposed on the second molding layer and the first and second vertical wires, a first redistribution pattern that is disposed in the insulating layer and is connected to the first vertical wire, and a second redistribution pattern that is disposed in the insulating layer and is connected to the second vertical wire.

15. The method according to claim 8, further comprising
connecting, after the forming the redistribution layer, an external connection terminal onto the redistribution layer.

16. The method according to claim 15, wherein the external connection terminal includes a solder ball.

17. A method of fabricating a semiconductor package, the method comprising:
offset stacking a plurality of semiconductor chips, each of the plurality of semiconductor chips having a chip pad, so that each chip pad is exposed;
forming vertical wires on each of the chip pads;
forming, with the vertical wires of the plurality of semiconductor chips fixed with a holder, a molding layer that seals the plurality of semiconductor chips and the vertical wires;
removing the holder; and
forming a redistribution layer on the second molding layer and the vertical wires, wherein the redistribution layer includes redistribution patterns with an alignment margin based on a fixed position of each of the vertical wires.
